(19) United States
(12) Patent Application Publication
(10) Pub. No.: US 2006/0051939 A1
(43) Pub. Date: Mar. 9, 2006

(54) Nitride semiconductor substrate and nitride semiconductor device using same

(75) Inventors: Masaru Kuramoto, Tokyo (JP); Chiaki Sasaoka, Tokyo (JP); Masahige Matsudate, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION, Tokyo 108-8001 (JP)

(21) Appl. No.: 10/537,611

(22) PCT Filed: Aug. 30, 2004
(86) PCT No.: PCT/JP04/12467

§ 371 Date: Jun. 3, 2005

(30) Foreign Application Priority Data
Aug. 29, 2003 (JP) 2003-308117

(51) Int. Cl. H01L 21/20

(52) U.S. Cl. 438/478

(57) ABSTRACT

Polycrystalline AlN 3 is deposited on the surface of an SiO₂ film (2) by a sputtering method, and a mask is formed. An Si-doped n-GaN layer 5 is then formed over the mask thus formed. Subsequently, an n-type cladding layer (6), which is formed from Si-doped n-type Al_{0.1}Ga_{0.9}N (silicon concentration 4×10¹⁷ cm⁻³, thickness 1.2 μm), an n-type light-trapping layer (7), which is formed from Si-doped n-type GaN, a multiple quantum well layer (8), which is formed from an In_{0.2}Ga_{0.8}N well layer and an Si-doped In_{0.05}Ga_{0.95}N barrier layer, a cap layer (9), which is formed from Mg-doped p-type Al_{0.2}Ga_{0.8}N, a p-type light-trapping layer (10), which is formed from Mg-doped p-type GaN, a p-type cladding layer (11), which is formed from Mg-doped p-type Al_{0.1}Ga_{0.9}N, and a p-type contact layer (12), which is formed from Mg-doped p-type GaN, are grown in sequence to form an LD layer structure.

### FIELD OF THE INVENTION

The present invention relates to a nitride semiconductor substrate and a nitride semiconductor device employing same.

### DESCRIPTION OF THE RELATED ART

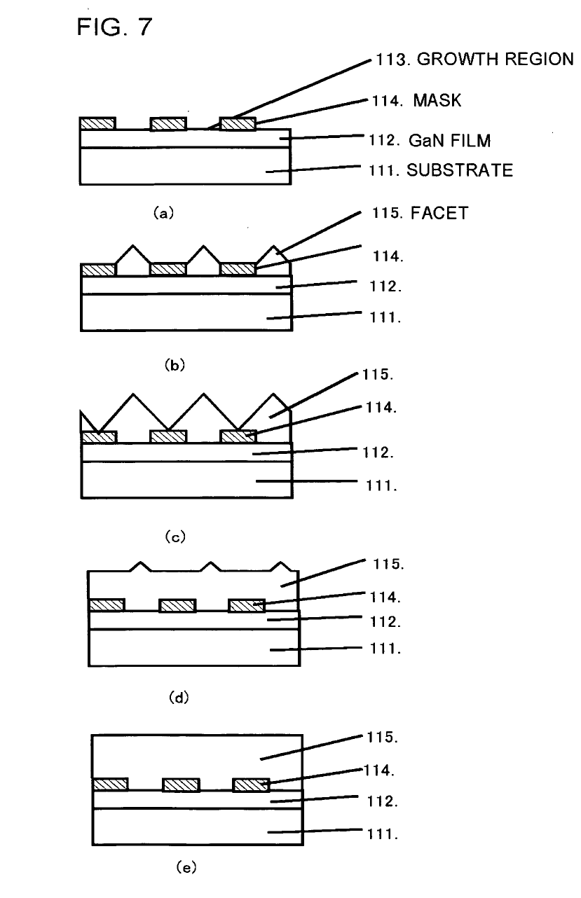

When fabricating a device using a nitride semiconductor, it is important to suppress threading dislocation in a semiconductor layer. With regard to a technique for suppressing such threading dislocation, a method is known as disclosed in Japanese Laid-open patent publication 11-251253 in which selective growth is carried out using a masking material. The method disclosed in Japanese Laid-open patent publication 11-251253 is explained below by reference to FIG. 7.

According to the method disclosed in this publication, a substrate in which a 1.2 μm thick GaN single film 112 is formed in advance on a (0001) face sapphire substrate 111 is prepared. An SiO₂ film is formed at a thickness of 200 nm on the surface of the GaN film 112, and divided into a mask 114 and a growth region 113 by a photolithographic process and wet etching. The growth region 113 and the mask 114 are formed in stripes with widths of 5 μm and 2 μm respectively. The direction of the stripes is <11-20> (FIG. 7(a)).

A GaN film 115 that grows in the growth region 113 is formed by a hydride VPE method using ammonia (NH₃) gas as a Group V starting material and gallium chloride (GaCl), which is a reaction product between hydrogen chloride (HCl) and the Group III starting material gallium (Ga). Dichlorosilane (SiH₂Cl₂) is used as an n-type dopant material. The substrate 111 is set in a hydride growth apparatus, and the temperature is increased to a growth temperature of 1000° C. under an atmosphere of hydrogen. After the growth temperature is stabilized, a facet structure comprising a {1-101} face of the GaN film 115 is grown in the growth region 113 by supplying HCl at a flow rate of 20 cc/min for about 5 minutes (FIG. 7 (b)). Growth is further carried out until the layer thickness reaches 140 μm while passing through the n-type dopant dichlorosilane (FIG. 7 (c), (d), (e)). In accordance with this technique, even when a GaN film of a few hundred microns is grown, a 2 inch size wafer that is crack-free over the whole surface can be provided. The dislocation density of the substrate is greatly reduced, and the dislocation density of the GaN single layer film 112, which was on the order of 10⁹/cm², can be reduced to on the order of 1×10⁷ to 2×10⁷/cm².

### SUMMARY OF THE INVENTION

However, even if the dislocation density is reduced by the above-mentioned technique, there are still 1×10⁷ to 2×10⁷/cm² dislocations remaining. A dislocation density of 1×10⁷ to 2×10⁷/cm² corresponds to 100 to 200 dislocations per stripe of an LD device when considering a semiconductor laser having a stripe width of 2 μm and a resonator length of 500 μm. It is known that dislocations shorten the device lifetime, and it is necessary to further reduce the dislocations.

It is an object of the present invention to provide a substrate or device that comprises a group III nitride semiconductor layer having reduced dislocations and good quality.

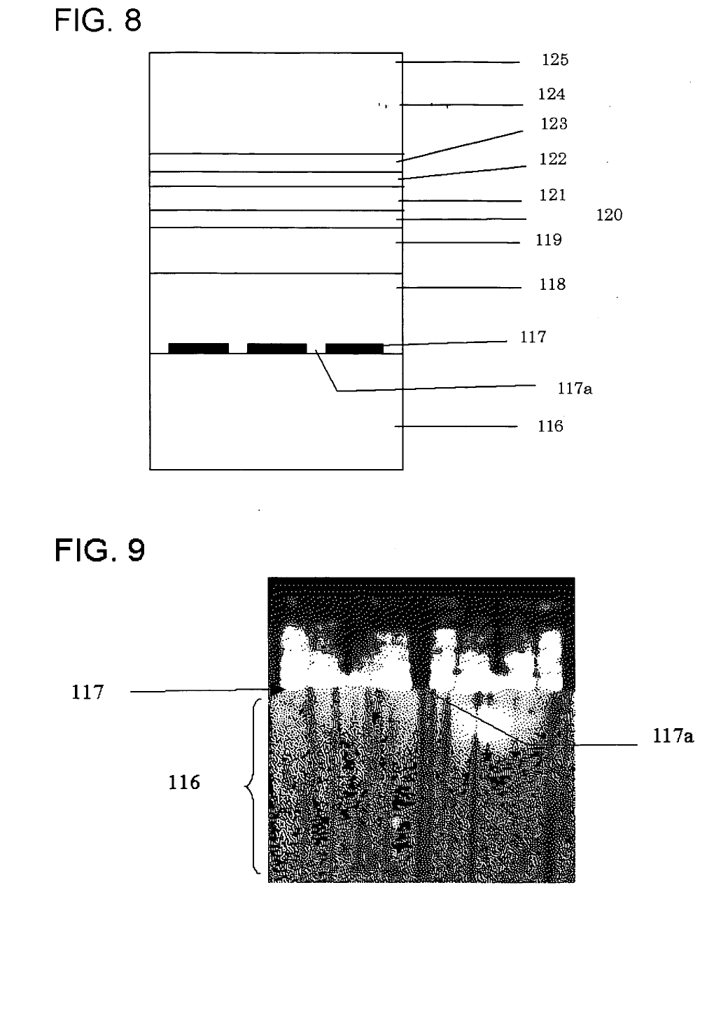

In order to reduce the dislocations of the group III nitride semiconductor layer, using a low dislocation substrate obtained by the process shown in FIG. 7, further forming a similar mask pattern thereon, and carrying out growth by metal-organic vapor phase epitaxy (MOVPE) can be considered. FIG. 8 is a diagram showing a semiconductor layer structure obtained by this method. This layer structure may be formed as follows.

Firstly, an SiO₂ stripe mask 117 is formed in the <11-20>direction by use of a substrate 116 described with reference to FIG. 7. The dislocation density in the vicinity of the surface of the substrate 116 is on the order of 2×10⁷/cm². The width of a mask opening 117a is 2 μm, and the SiO₂ mask region is 18 μm. In MOVPE equipment Si-doped GaN is formed in the opening 117a of a wafer having the above-mentioned mask formed thereon. The GaN layer that has grown in the mask opening continues to grow in the lateral direction and unites with an adjacent GaN layer via the mask (hereinafter, this portion is called a joined-up portion).

The GaN layer is planarized in this way to form an n-GaN layer 118. An n-type cladding layer 119, which is formed from Si-doped n-type Al_{0.1}Ga_{0.9}N (silicon concentration 4×10¹⁷ cm⁻³, thickness 1.2 μm), and an n-type light-trapping layer 120, which is formed from Si-doped n-type GaN (silicon concentration 4×10¹⁷ cm⁻³, thickness 0.1 μm) are subsequently formed on top of the n-GaN substrate 118. Further grown in sequence on top thereof are a multiple quantum-well (MQW) layer 121 (number of wells 3) formed from an In_{0.2}Ga_{0.8}N well layer (thickness 4 nm) and an Si-doped, In_{0.05}Ga_{0.95}N barrier layer (silicon concentration 5×10¹⁸ cm⁻³ thickness 6 nm), a cap layer 122 formed from Mg-doped p-type Al_{0.2}Ga_{0.8}N, a p-type light-trapping layer 123 formed from Mg-doped p-type GaN (Mg concentration 2×10¹⁷ cm⁻³, thickness 0.1 μm), a p-type cladding layer 124 formed from Mg-doped p-type Al_{0.1}Ga_{0.9}N (Mg concentration 2×10¹⁷ cm⁻³, thickness 0.5 μm), and a p-type contact layer 125 formed from Mg-doped p-type GaN (Mg concentration 2×10¹⁷ cm⁻³, thickness 0.1 μm), thus forming an LD structure.

In order to investigate the dislocation behavior of the LD layer structure thus fabricated, a cross sectional cathodoluminescence (CL) image was examined, and the results are shown in FIG. 9. It is clear from FIG. 9 that there are a large number of dark spots and dark lines present in the layer formed on the substrate. In a CL image, as described in, for example, Sugahara, M. Hao, T. Wang, D. Nakagawa, Y. Naoi, K. Nishino, and S. Sakai, Jpn. J. Appl. Phys. vol. 37, no. 10B, pp. L1195-L1198, October 1998, places where dislocations are present appear as dark spots since dislocations contribute to light not being emitted. It is therefore thought that these dark lines and dark spots represent dislocations. It has been found from the above that new dislocations are generated as a result of selective growth using a second mask pattern. This phenomenon is thought to occur even in a case where a first mask pattern in FIG. 7 is used, but since the dislocation density in the substrate of the first mask pattern is very high, it can not be distinguished by cross-sectional CL observation whether or not there are newly generated dislocations.

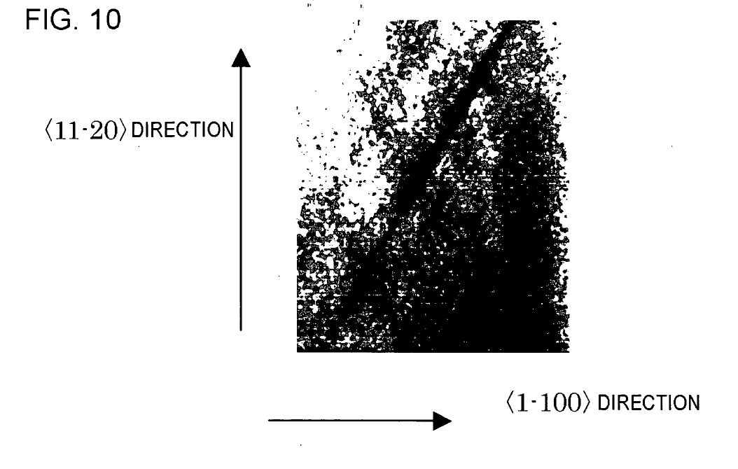

FIG. 10 is a planar CL image, it which an InGaN luminescence image is observed when applying an electron beam from above the sample of FIG. 8. In FIG. 10, a large number of dark lines are observed in the planar CL image. This means that there are dislocations present within the InGaN layer 121, which is formed from InGaN.

However, when the sample of FIG. 9 was actually examined using a transmission electron microscope, dislocations were also present in the in-plane direction of layers other than the multiple quantum-well (MQW) layer 121. In this way, it has become clear that, with regard to the layer structure of FIG. 8, there is still room for further improvement in terms of device characteristics and device lifetime.

The behavior and cause of the occurrence of these dislocations are explained below. Many dislocations present in the vicinity of the mask are thought to have many sources; for example, a dislocation that has bent due to lateral growth of a dislocation inherited from the substrate, a dislocation generated at the interface between the mask and laterally grown nitride semiconductor crystals, and a dislocation generated at the growth surface of a nitride semiconductor during lateral growth. The first dislocation propagated from the substrate depends on the substrate dislocation density, but the occurrence of other dislocations and the cause of these dislocations being introduced into the device layer structure are thought to depend on the affinity between the masking material and the nitride semiconductor crystals and the stress during growth. When the sample of FIG. 8 was subjected to cross-sectional TEM observation in the <11-20> direction, it was confirmed that a large number of dislocations were present in the <11-20> direction of the nitride semiconductor in the vicinity of the masking material. It is therefore surmised that the dislocations present on the mask are bent in the <11-20> direction by the influence of stress due to the mask, etc. A dislocation that has once been bent in the <11-20> direction runs through within the horizontal plane of the substrate and, for various reasons, slides in another direction within the horizontal plane (e.g., a direction equivalent to the <1-100> direction). It is surmised that this is the dislocation identified in FIG. 9 and in the cross-sectional TEM observation.

As a result of an investigation by the present inventors, it has been found that, in the sample of FIG. 8, a dislocation is propagated within the horizontal plane as described above, and such a dislocation is also introduced into the InGaN layer, which is an active layer.

That is, the following has been clarified as a result of the investigation by the present inventors;
(i) when a mask is provided on a low dislocation substrate and a group III nitride semiconductor is grown thereon, many dislocations develop from the vicinity of the mask, and
(ii) the development of this type of dislocation is marked when a substrate having a low dislocation density is used.

Such a phenomenon becomes more apparent for a substrate in which dislocations have been reduced to less than 10⁷/cm².

Although the reason for the above-mentioned phenomenon occurring is not entirely clear, it is surmised that, when the substrate dislocation density is high, many dislocations are present around a mask for re-growth, and these dislocations relieve the crystal strain, whereas in a substrate having a low dislocation density (e.g., less than 10⁷/cm²) such relief of the crystal strain occurs very little.

Based on such a conjecture, the present inventors have conceived the idea that, when a group III nitride semiconductor is mask-grown on a low dislocation substrate, it is effective to intentionally form on the mask a region that has the action of relieving crystal strain, and the present invention has thus been accomplished.

According to the present invention, there is provided a nitride semiconductor substrate comprising a group III nitride semiconductor substrate, a mask formed over the group III nitride semiconductor substrate, and a semiconductor multilayer film formed above the mask, a polycrystalline material being deposited on the surface of the mask.

Furthermore, according to the present invention, there is provided a nitride semiconductor device comprising a group III nitride semiconductor substrate, a mask formed over the group III nitride semiconductor substrate, and formed above the mask a semiconductor multilayer film that includes an active layer, a polycrystalline material being deposited on the surface of the mask.

In accordance with the present invention, the crystal strain on the mask is relieved by the action of the polycrystalline material deposited on the surface of the mask, and as a result the crystal quality of the semiconductor multilayer film formed above the mask is improved. In this semiconductor device, since the mask having the polycrystalline material deposited on the surface thereof is provided underneath the active layer, the quality of the active layer can be improved outstandingly.

As described above, according to the investigation by the present inventors, when a substrate having relatively few dislocations such as a group III nitride semiconductor substrate is used, dislocations occurring in the vicinity of the mask on the substrate become a problem. In accordance with the present invention, since such dislocations can be reduced effectively, the problem characteristic of such use of a group III nitride semiconductor substrate can be solved effectively while taking advantage of the use of a group III nitride semiconductor substrate.

The group III nitride semiconductor substrate of the present invention preferably has a dislocation density in the vicinity of the surface thereof of 1×10⁷/cm² or less. The present invention solves effectively the problem characteristic of a case in which a semiconductor layer is grown from a mask on such a low dislocation substrate, that is, the problem that new dislocations develop in the vicinity of the mask, and when such a substrate is used, a more outstanding effect can be exhibited. The dislocation density of a substrate can be measured by a method in which the surface of the substrate is treated with a liquid reagent so as to form etch pits and the density thereof is measured, a method in which a cross section of a structure having a semiconductor layer formed on a substrate is examined by an electron microscope, a method in which a cathodoluminescence image is examined, etc. There among, it is preferable to use the method employing cathodoluminescence because of the high measurement accuracy.

As hereinbefore described, according to the present invention, there is provided a substrate or device comprising a group III nitride semiconductor layer having reduced dislocations and good quality.

### BRIEF DESCRIPTION OF THE DRAWINGS

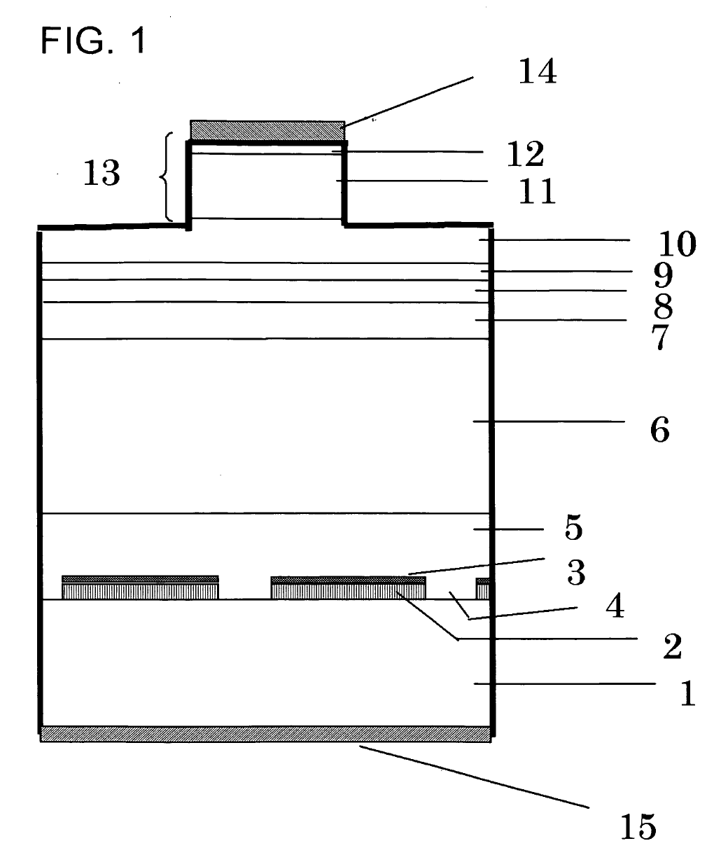

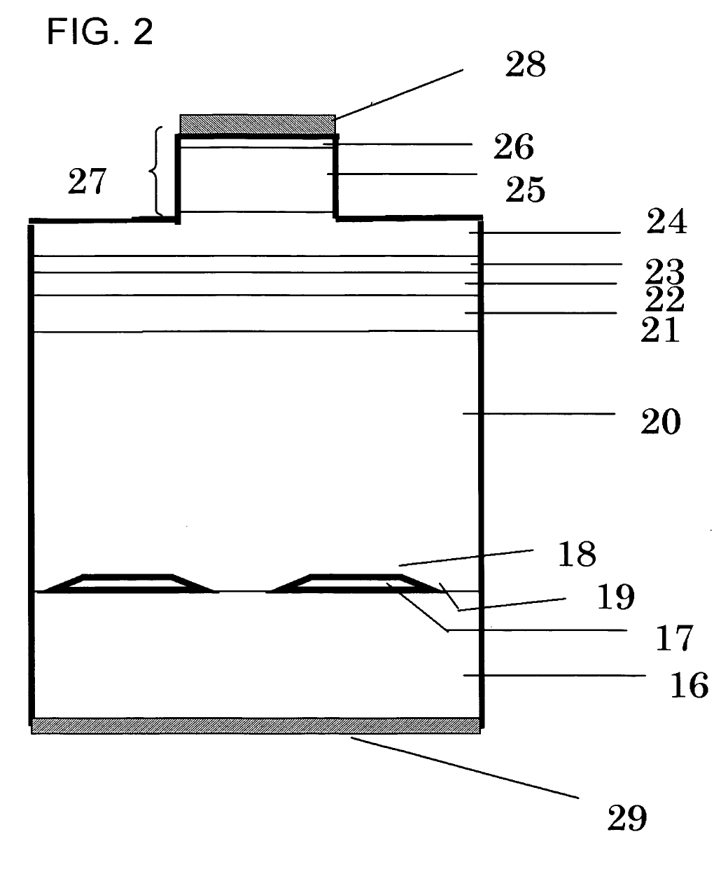

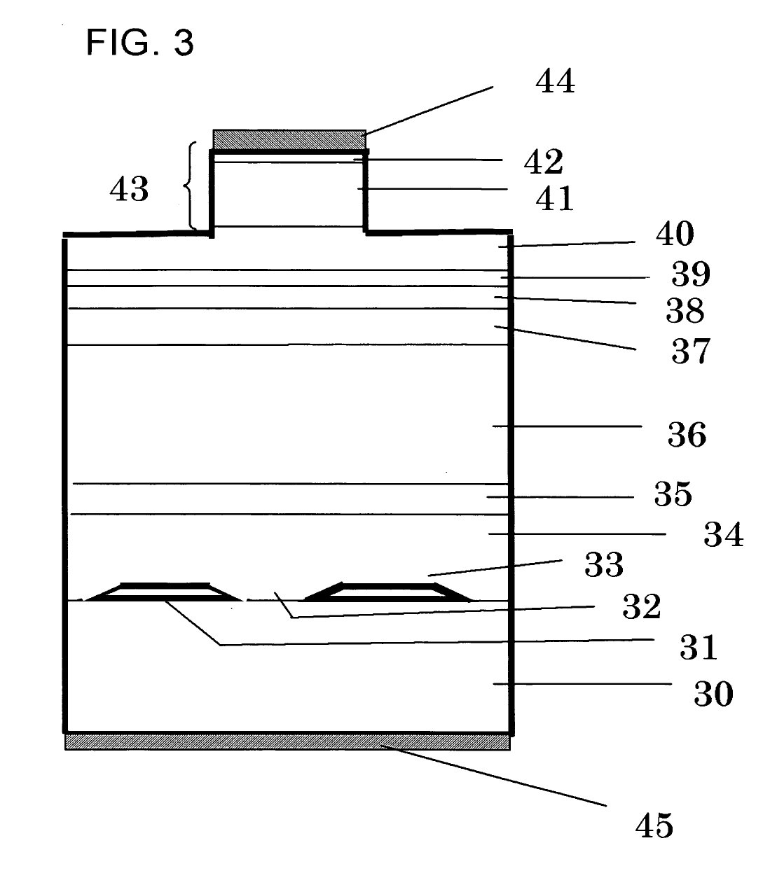

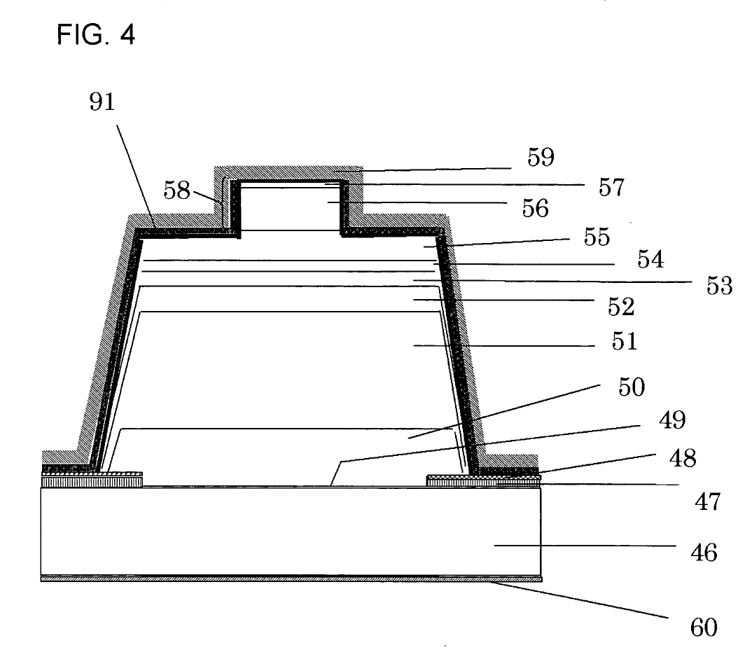

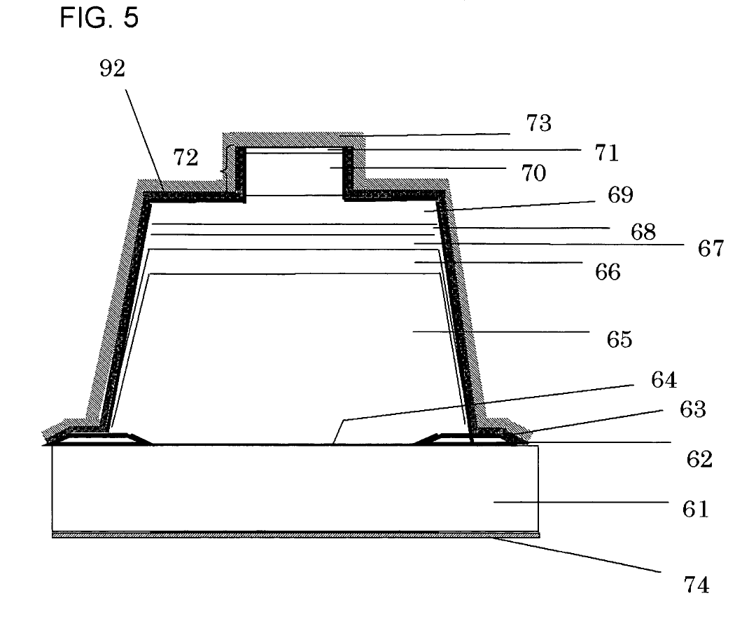

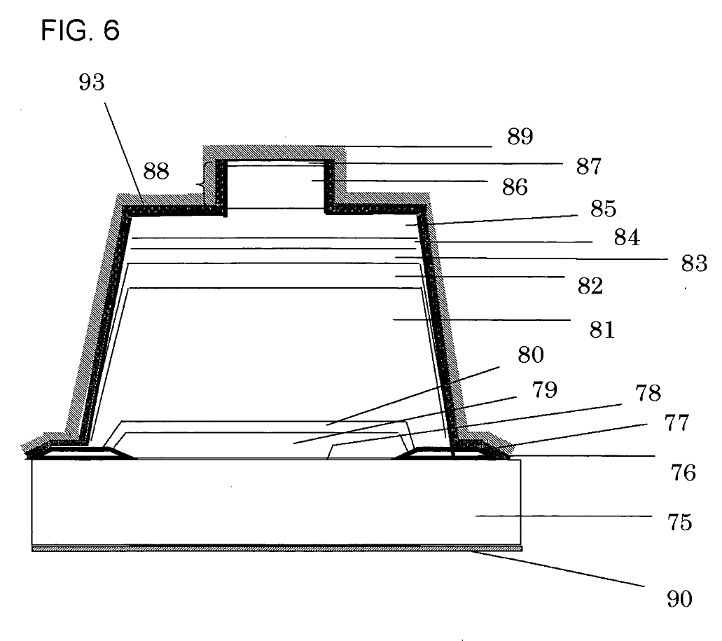

The above-mentioned object, other objects, characteristics, and advantages will become apparent from an explanation of a preferred embodiment that will be described below by reference to the attached drawings.

[FIG. 1] A sectional view of a semiconductor device related to an example.

[FIG. 2] A sectional view of a semiconductor device related to an example.

[FIG. 3] A sectional view of a semiconductor device related to an example.

[FIG. 4] A sectional view of a semiconductor device related to an example.

[FIG. 5] A sectional view of a semiconductor device related to an example.

[FIG. 6] A sectional view of a semiconductor device related to an example.

[FIG. 7] Sectional views showing steps of a process for fabricating a conventional semiconductor device.

[FIG. 8] A diagram showing a layer structure obtained by growing a semiconductor layer via a mask opening on top of a low dislocation substrate.

[FIG. 9] A diagram showing the result of examining a cross-sectional cathodoluminescence (CL) image of the structure shown in FIG. 8.

[FIG. 10] A diagram showing the result of examining a planar cathodoluminescence (CL) image of the structure shown in FIG. 8.

### DETAILED DESCRIPTION OF THE INVENTION

In the present invention, various materials can be used as a polycrystalline material. For example, it may be a material containing aluminum and nitrogen as essential elements. For example, a material such as AlGaN, AlN, or InAlGaN may be used. When such a material is selected, a structure suitable for reducing crystal strain can be achieved.

The surface of a mask having the polycrystalline material formed thereon preferably has a void structure. By so doing, it is possible to reduce the crystal strain still more effectively by the action of the voids.

In the present invention, the mask may be provided directly on the surface of a group III nitride semiconductor substrate or via a semiconductor layer or an insulating layer. When the mask is provided directly on the surface of the substrate, the effect in reducing crystal strain can be obtained more reliably.

The present invention exhibits a more outstanding effect when a group III nitride semiconductor substrate having a dislocation density in the vicinity of the surface of 1×10⁷ or less is used. As described above, the present invention is effective in suppressing dislocations that develop from the vicinity of a mask on a low dislocation substrate. With regard to the substrate having a dislocation density of 1×10⁷ or less, although dislocations originating from the substrate are reduced, there is the problem that other dislocations due to crystal strain in the vicinity of the mask occur. Such a problem is particularly prominent in the case of the above-mentioned low dislocation density substrate, but in accordance with the present invention, this problem can be solved effectively, and the problems characteristic of a case in which a low dislocation substrate is used can be solved while taking advantage of the low dislocation substrate.

### EXAMPLES

The present invention is explained in further detail below by reference to examples. The examples below employed a substrate obtained, using a similar method to that explained in FIG. 7, by growing a GaN film using a mask that was thicker than usual. This mask has a mask width of 2 μm and a mask height of 1.7 μm, and a substrate having less surface dislocations than one obtained by the method of FIG. 7 can be obtained.

A preferred embodiment of the nitride semiconductor substrate according to the present invention and a semiconductor laser fabricated by employing same are explained below by reference to the examples.

### Example 1

The structure of a semiconductor laser according to this example is shown in FIG. 1.

This semiconductor laser can be fabricated as follows. Firstly, an SiO₂ film 2 is deposited on a GaN substrate 1 having a dislocation density in the vicinity of the substrate of 9×10⁶/cm² by a CVD method or a plasma CVD method. Subsequently, polycrystalline AlN 3 is deposited by a sputtering method, and a resist stripe mask is formed in the <11-20> direction. The mask width is 18 μm and the opening width is 2 μm.

When the polycrystalline AlN 3 is formed, the following procedure is carried out.
(i) After forming the SiO₂ film 2, a wafer is subjected to ultrasonic cleaning with butanone and ethanol, washing with pure water, etching with buffered hydrofluoric acid for 1 sec, washing again with pure water, and then drying by blowing nitrogen.
(ii) Subsequently, it is inserted into sputtering equipment and deposition is carried out by AlN sputtering while maintaining the substrate temperature at 50° C. or higher.

The polycrystalline AlN 3 and the SiO₂ film 2 are subsequently subjected to etching by dry etching and wet etching methods so that the surface of the substrate is exposed at an opening 4.

Subsequently, Si-doped GaN is formed in the opening using the above-mentioned mask-formed wafer in MOVPE equipment. With regard to MOVPE growth subsequent to the opening being formed, after first holding the substrate at 600° C. for 5 minutes while passing through ammonia gas, it is heated to 1080° C., which is the growth temperature for GaN, and after waiting for 30 seconds growth is started.

The GaN layer that is grown from the mask opening subsequently grows laterally and unites with an adjacent GaN layer via the mask (hereinafter, this portion is called a joined-up portion).

In this way the GaN layer is planarized, an n-GaN layer 5 is formed, and a semiconductor substrate comprising the mask having formed thereon the polycrystalline AlN 3 is formed. Voids are introduced in the n-GaN layer 5 around areas where the polycrystalline AlN 3 is formed.

In this example, growth of semiconductor layers is subsequently carried out in succession to form a device. Firstly, an n-type cladding layer 6, which is formed from Si-doped n-type Al_{0.1}Ga_{0.9}N (silicon concentration 4×10¹⁷ cm³, thickness 1.2 μm), an n-type light-trapping layer 7, which is formed from Si-doped n-type GaN (silicon concentration 4×10¹⁷ cm⁻³, thickness 0.1 μm), a multiple quantum-well (MQW) layer 8 (number of wells 3), which is formed from an In_{0.2}Ga_{0.8}N (thickness 4 nm) well layer and an Si-doped In_{0.05}Ga_{0.95}N (silicon concentration 5×10¹⁸ cm⁻³, thickness 6 nm) barrier layer, a cap layer 9, which is formed from Mg-doped p-type Al_{0.2}Ga_{0.8}N, a p-type light-trapping layer 10, which is formed from Mg-doped p-type GaN (Mg concentration 2×10¹⁷ cm⁻³, thickness 0.1 μm), a p-type cladding layer 11, which is formed from Mg-doped p-type Al_{0.1}Ga_{0.9}N (Mg concentration 2×10¹⁷ cm³, thickness 0.5 μm), and a p-type contact layer 12, which is formed from Mg-doped p-type GaN (Mg concentration 2×10¹⁷ cm⁻³, thickness 0.1 μm) are grown in sequence so as to form an LD layer structure. A resist stripe mask is subsequently formed in the <11-20> direction by a standard exposure technique, and etching is carried out by a dry etching method so as to form a ridge 13. A p-electrode 14 made from Ni/Pt/Au is then formed on the p contact layer side, and an n-electrode 15 made from Ti/Al is formed on the n substrate side.

In this way, a wafer in which polycrystalline AlN is deposited on an SiO₂ masking material and selective growth is then carried out has a very low dislocation density on the mask. The dislocations in the <11-20> direction therefore also decrease, and dislocations present in the laser structure layer above the mask can be reduced.

### Example 2

The structure of a semiconductor laser according to this example is shown in FIG. 2.

This semiconductor laser can be fabricated as follows. Firstly, an SiO₂ film 17 is deposited on a GaN substrate 16 having a dislocation density in the vicinity of the substrate surface of 5×10⁵/cm², and a resist stripe mask is formed in the <11-20> direction. The mask width is 18 μm and the opening width is 2 μm. The mask is formed by etching the SiO₂ film 17 by a wet etching method so that the substrate surface is exposed in the opening 19.

The mask thus formed is subjected to ultrasonic cleaning with butanone and ethanol and washing with pure water. The wafer is then subjected to etching with buffered hydrofluoric acid for 1 sec, washing again with pure water, then washing with nitric acid at 100° C. for 30 minutes, washing again with pure water, and then drying by blowing nitrogen.

An Si-doped n-type Al_{0.05}Ga_{0.95}N layer 18 is formed, using MOVPE equipment, in the opening of the wafer having the mask formed thereon as described above. In this process, the growth conditions are set so that polycrystalline AlGaN material is deposited on the SiO₂ mask. That is, the substrate is held and heated to 1080° C., which is the growth temperature for AlGaN, while passing through ammonia gas, and after waiting for 60 seconds while passing through silane, growth is started. By so doing, polycrystalline AlGaN material is deposited on top of the mask. Voids are introduced in the area around the AlGaN polycrystalline material.

In this stage, the substrate may be taken out from a film formation chamber to give a nitride semiconductor substrate, but in this example growth of semiconductor layers is continued to form a device.

The substrate temperature is set at 1050° C., the AlGaN layer is grown laterally, unites with an adjacent AlGaN layer, and is planarized to form an n-cladding (silicon concentration 4×10¹⁷ cm⁻³, thickness 2 μm) layer 20 from n-Al_{0.08}Ga_{0.92}N.

Subsequently, an n-type light-trapping layer 21, which is formed from Si-doped n-type GaN (silicon concentration 4×10¹⁷ cm⁻³, thickness 0.1 μm), a multiple quantum-well (MQW) layer 22 (number of wells 3), which is formed from an In_{0.2}Ga_{0.8}N (thickness 4 nm) well layer and an Si-doped In_{0.05}Ga_{0.95}N (silicon concentration 5×10¹⁸ cm⁻³, thickness 6 nm) barrier layer, a cap layer 23, which is formed from Mg-doped p-type Al_{0.2}Ga_{0.8}N, a p-type light-trapping layer 24, which is formed from Mg-doped p-type GaN (Mg concentration 2×10¹⁷ cm⁻³, thickness 0.1 μm), a p-type cladding layer 25, which is formed from Mg-doped p-type Al_{0.1}Ga_{0.9}N (Mg concentration 2×10¹⁷ cm⁻³, thickness 0.5 μm), and a p-type contact layer 26, which is formed from Mg-doped p-type GaN (Mg concentration 2×10¹⁷ cm⁻³, thickness 0.1 μm) are grown in sequence so as to form an LD layer structure. A resist stripe mask is subsequently formed in the <11-20> direction by a standard exposure technique, and etching is carried out by a dry etching method so as to form a ridge 27. A p-electrode 28 made from Ni/Pt/Au is then formed on the p contact layer side, and an n-electrode 29 made from Ti/Al is formed on the n substrate side.

In this way, a wafer in which polycrystalline AlGaN is deposited on an SiO₂ masking material when growing and selective growth is then carried out has a very low dislocation density on the mask. Dislocations in the <11-20> direction therefore also decrease, and dislocations present in the laser structure layer above the mask can be reduced.

### Example 3

The structure of a semiconductor laser according to this example is shown in FIG. 3. This semiconductor laser can be fabricated as follows. Firstly, an SiO₂ film 31 is deposited on a GaN substrate 30 having a dislocation density in the vicinity of the substrate surface of 5×10⁶/cm², and a resist stripe mask is formed in the <11-20> direction. The mask width is 20 μm and the opening width is 2 μm. The SiO₂ film 31 is subjected to etching by a wet etching method so that the surface of the substrate is exposed in an opening 32. An Si-doped n-type Al_{0.05}Ga_{0.95}N layer 33 is formed, using MOVPE equipment, in the opening of the wafer having the above-mentioned mask. In this process, the substrate temperature is set at 500° C. or higher so that polycrystalline AlGaN material is deposited on the SiO₂ mask. The mask formed is subjected to the same processing as in Example 2 so that the polycrystalline material is deposited appropriately. By so doing, the polycrystalline AlGaN material is deposited on top of the mask. Voids are introduced in the area around the polycrystalline AlGaN material.

In this stage, the substrate may be taken out from a film formation chamber to give a nitride semiconductor substrate, but in this example growth of semiconductor layers is continued to form a device.

The substrate temperature is then set at 1050° C., the AlGaN layer is grown laterally, unites with an adjacent AlGaN layer, and is planarized to form an n-AlGaN layer 34. Subsequently, an Si-doped n-type In_{0.1}Ga_{0.8}N (silicon concentration 4×10¹⁷ cm³, thickness 0.1 μm) intermediate layer 35, an n-type cladding layer 36, which is formed from Si-doped n-type Al_{0.07}Ga_{0.93}N (silicon concentration 4×10¹⁷ cm³, thickness 0.8 μm), an Si-doped n-type light-trapping layer 37, which is formed from Si-doped n-type GaN (silicon concentration 4×10¹⁷ cm⁻³, thickness 0.1 μm), a multiple quantum-well (MQW) layer 38 (number of wells 3), which is formed from an In_{0.2}Ga_{0.8}N (thickness 4 nm) well layer and an Si-doped In_{0.05}Ga_{0.95}N (silicon concentration 5×10¹⁸ cm⁻³, thickness 6 nm) barrier layer, a cap layer 39, which is formed from Mg-doped p-type Al_{0.2}Ga_{0.8}N, a p-type light-trapping layer 40, which is formed from Mg-doped p-type GaN (Mg concentration 2×10¹⁷ cm⁻³, thickness 0.1 μm), a p-type cladding layer 41, which is formed from Mg-doped p-type Al_{0.1}Ga_{0.9}N (Mg concentration 2×10¹⁷ cm⁻³, thickness 0.5 μm), and a p-type contact layer 42, which is formed from Mg-doped p-type GaN (Mg concentration 2×10¹⁷ cm⁻³, thickness 0.1 μm) are grown in sequence so as to form an LD layer structure.

Subsequently, a resist stripe mask is formed in the <11-20> direction by a standard exposure technique, and etching is carried out by a dry etching method so as to form a ridge 43. A p-electrode 44 made from Ni/Pt/Au is then formed on the p contact layer side, and an n-electrode 45 made from Ti/Al is formed on the n substrate side.

In this way, a wafer in which polycrystalline AlGaN is deposited on an SiO₂ masking material when growing and selective growth is then carried out has a very low dislocation density on the mask. Dislocations in the <11-20> direction therefore also decrease, and dislocations present in the laser structure layer above the mask can be reduced.

### Example 4

This example shows a case in which a groove used for device separation is formed by selective growth. The structure of a semiconductor laser according to this example is shown in FIG. 4. This semiconductor laser can be fabricated as follows. Firstly, an SiO₂ film 47 is deposited on a GaN substrate 46 having a dislocation density in the vicinity of the substrate of 9×10⁶/cm² by a CVD method. Subsequently, polycrystalline AlN 48 is deposited by a sputtering method and a resist stripe mask is formed in the <11-20> direction. The mask width is 30 μm and the opening width is 200 μm.

When the polycrystalline AlN 48 is formed, the following procedure is carried out.
(i) After forming the SiO₂ film 2, a wafer is subjected to ultrasonic cleaning with butanone and ethanol, washing with pure water, etching with buffered hydrofluoric acid for 1 sec, washing again with pure water, and then drying by blowing nitrogen.
(ii) Subsequently, it is inserted into sputtering equipment and deposition is carried out by AlN sputtering while maintaining the substrate temperature at 50° C. or higher.

The polycrystalline AlN 48 and the SiO₂ film 47 are subsequently subjected to etching by dry etching and wet etching methods so that the surface of the substrate is exposed at an opening 49. Si-doped GaN is formed, using MOVPE equipment, in the opening of the wafer having formed thereon the above-mentioned mask, and the GaN layer is grown laterally, unites with an adjacent GaN layer, and is planarized to form an n-GaN layer 50.

In this way, the GaN layer is planarized, the n-GaN layer 50 is formed, and a semiconductor substrate comprising the mask having formed thereon the polycrystalline AlN 48 is formed. Voids are introduced in the n-GaN layer 50 around areas where the polycrystalline AlN 48 is formed.

Subsequently, an n-type cladding layer 51, which is formed from Si-doped n-type Al_{0.1}Ga_{0.9}N (silicon concentration 4×10¹⁷ cm⁻³, thickness 1.2 μm), an n-type light-trapping layer 52, which is formed from Si-doped n-type GaN (silicon concentration 4×10¹⁷ cm⁻³, thickness 0.1 μm), a multiple quantum-well (MQW) layer 53 (number of wells 3), which is formed from an In_{0.2}Ga_{0.8}N (thickness 4 nm) well layer and an Si-doped In_{0.05}Ga_{0.95}N (silicon concentration 5×10¹⁸ cm⁻³, thickness 6 nm) barrier layer, a cap layer 54, which is formed from Mg-doped p-type Al_{0.2}Ga_{0.8}N, a p-type light-trapping layer 55, which is formed from Mg-doped p-type GaN (Mg concentration 2×10¹⁷ cm⁻³, thickness 0.1 μm), a p-type cladding layer 56, which is formed from Mg-doped p-type Al_{0.2}Ga_{0.9}N (Mg concentration 2×10¹⁷ cm⁻³, thickness 0.5 μm), and a p-type contact layer 57, which is formed from Mg-doped p-type GaN (Mg concentration 2×10¹⁷ cm⁻³, thickness 0.1 μm) are grown in sequence so as to form an LD layer structure. A resist stripe mask is subsequently formed in the <11-20> direction by a standard exposure technique, and etching is carried out by a dry etching method so as to form a ridge 58. Subsequently, an SiO₂ dielectric film 91 and a p-electrode 59 made from Ni/Pt/Au are formed on the p side, and an n-electrode 60 made from Ti/Al is formed on the n substrate side. Devices are then separated at the separation groove so as to give semiconductor laser devices.

In this way, a wafer in which polycrystalline AlN is deposited on an SiO₂ masking material and selective growth is then carried out has a very low dislocation density on the mask. Dislocations in the <11-20> direction therefore also decrease, and dislocations present in the laser structure layer above the mask can be reduced. Although the region where there is masking material and the region where the device has been fabricated are separated from each other by on the order of 100 μm, once a dislocation is generated, the dislocation is introduced within the layer plane, and there is a large influence in this case. In practice, when a planar CL image of a sample having no polycrystalline layer above the mask was examined, a dislocation was present within the plane as in FIG. 10.

### Example 5

The structure of a semiconductor laser according to this example is shown in FIG. 5. This semiconductor laser can be fabricated as follows. An SiO₂ film 62 is deposited on a GaN substrate 61 having a dislocation density in the vicinity of the substrate surface of 2×10⁶/cm², and a resist stripe mask is formed in the <11-20> direction. The mask width is 40 μm and the opening width is 260 μm. The mask is formed by etching the SiO₂ film 62 by a wet etching method so that the substrate surface is exposed in the opening 64.

The mask thus formed is subjected to ultrasonic cleaning with butanone and ethanol and washing with pure water. The wafer is then subjected to etching with buffered hydrofluoric acid for 1 sec, washing again with pure water, then washing with nitric acid at 100° C. for 30 minutes, washing again with pure water, and then drying by blowing nitrogen.

A cladding layer 65 made from Si-doped n-type Al_{0.06}Ga_{0.94}N layer (silicon concentration 4×10¹⁷ cm⁻³, thickness 2.5 μm) is formed, using MOVPE equipment, in the opening of the wafer having the mask formed thereon as described above. In this process, growth conditions such as the substrate temperature are set so that polycrystalline AlGaN 63 is deposited on the SiO₂ mask. That is, the substrate is held and heated to 1080° C., which is the growth temperature for AlGaN, while passing through ammonia gas, and after waiting for 60 seconds while passing through silane, growth is started. By so doing, polycrystalline AlGaN material is deposited on top of the mask. Voids are introduced in the area around the AlGaN polycrystalline material.

In this stage, the substrate may be taken out from a film formation chamber to give a nitride semiconductor substrate, but in this example growth of semiconductor layers is continued to form a device.

Subsequently, an n-type light-trapping layer 66, which is formed from Si-doped n-type GaN (silicon concentration 4×10¹⁷ cm³, thickness 0.1 μm), a multiple quantum-well (MQW) layer 67 (number of wells 3), which is formed from an In_{0.2}Ga_{0.8}N (thickness 4 nm) well layer and an Si-doped In_{0.05}Ga_{0.95}N (silicon concentration 5×10¹⁸ cm⁻³, thickness 6 nm) barrier layer, a cap layer 68, which is formed from Mg-doped p-type Al_{0.2}Ga_{0.8}N, a p-type light-trapping layer 69, which is formed from Mg-doped p-type GaN (Mg concentration 2×10¹⁷ cm⁻³, thickness 0.1 μm), a p-type cladding layer 70, which is formed from Mg-doped p-type Al_{0.2}Ga_{0.8}N (Mg concentration 2×10¹⁷ cm⁻³, thickness 0.5 μm), and a p-type contact layer 71, which is formed from Mg-doped p-type GaN (Mg concentration 2×10¹⁷ cm⁻³, thickness 0.1 μm) are grown in sequence so as to form an LD layer structure. A resist stripe mask is subsequently formed in the <11-20> direction by a standard exposure technique, and etching is carried out by a dry etching method so as to form a ridge 72. Subsequently, an SiO₂ dielectric film 92 is deposited on the p side, a p-electrode 73 made from Ni/Pt/Au is then formed on the p contact layer side, and an n-electrode 74 made from Ti/Al is formed on the n substrate side. Devices are then separated at a separation groove so as to give semiconductor laser devices.

In this way, a wafer in which polycrystalline AlGaN is deposited on an SiO₂ masking material when growing and selective growth is then carried out has a very low dislocation density on the mask. Dislocations in the <11-20> direction therefore also decrease, and dislocations present in the laser structure layer above the mask can also be reduced. Although the area where the masking material is present and the area where the devices are fabricated are separated from each other by on the order of 130 μm, once a dislocation occurs, the dislocation is introduced within a layer plane, and there is therefore a large influence in this case.

### Example 6

The structure of a semiconductor laser according to this example is shown in FIG. 6. In this example, an SiO₂ film 76 is deposited on a GaN substrate 75 having a dislocation density in the vicinity of the substrate surface of 9×10⁶/cm², and a resist stripe mask is formed in the <11-20> direction. The mask width is 50 μm and the opening width is 300 μm. The SiO₂ film 76 is subjected to etching by a wet etching method so that the surface of the substrate is exposed in an opening 78, thus forming the mask.

The mask thus formed is subjected to ultrasonic cleaning with butanone and ethanol and washing with pure water. The wafer is then subjected to etching with buffered hydrofluoric acid for 1 sec, washing again with pure water, then washing with nitric acid at 100° C. for 30 minutes, washing again with pure water, and then drying by blowing nitrogen.

Si-doped n-type Al_{0.05}Ga_{0.95}N is formed, using MOVPE equipment, in the opening of the wafer having the above-mentioned mask formed thereon. In this process, the substrate temperature is set at 500° C. or higher so that polycrystalline AlGaN 77 is deposited on the SiO₂ mask. Specifically, the substrate is held and heated at 1080° C., which is the growth temperature for GaN, while passing through ammonia gas, and after waiting for 60 seconds while passing through silane growth is started. By so doing, the polycrystalline AlGaN material is deposited on top of the mask. Voids are introduced in the area around the polycrystalline AlGaN material.

In this stage, the substrate may be taken out from a film formation chamber to give a nitride semiconductor substrate, but in this example growth of semiconductor layers is continued to form a device.

The substrate temperature is then set at 1050° C., and an n-Al_{0.05}Ga_{0.95}N layer 79 is formed. Subsequently, an Si-doped n-type In_{0.1}Ga_{0.9}N (silicon concentration 4×10¹⁷ cm⁻³, thickness 0.1 μm) intermediate layer 80, an n-type cladding layer 81, which is formed from Si-doped n-type Al_{0.07}Ga_{0.93}N (silicon concentration 4×10¹⁷ cm⁻³, thickness 0.8 μm), an n-type light-trapping layer 82, which is formed from Si-doped n-type GaN (silicon concentration 4×10¹⁷ cm⁻³, thickness 0.1 μm), a multiple quantum-well (MQW) layer 83 (number of wells 3), which is formed from an In_{0.2}Ga_{0.8}N (thickness 4 nm) well layer and an Si-doped In_{0.05}Ga_{0.95}N (silicon concentration 5×10¹⁸ cm⁻³, thickness 6 nm) barrier layer, a cap layer 84, which is formed from Mg-doped p-type Al_{0.2}Ga_{0.8}N, a p-type light-trapping layer 85, which is formed from Mg-doped p-type GaN (Mg concentration 2×10¹⁷ cm⁻³, thickness 0.1 μm), a p-type cladding layer 86, which is formed from Mg-doped p-type Al_{0.1}Ga_{0.9}N (Mg concentration 2×10¹⁷ cm⁻³, thickness 0.5 μm), and a p-type contact layer 87, which is formed from Mg-doped p-type GaN (Mg concentration 2×10¹⁷ cm⁻³, thickness 0.1 μm) are grown in sequence so as to form an LD layer structure.

Subsequently, a resist stripe mask is formed in the <11-20> direction by a standard exposure technique, and etching is carried out by a dry etching method so as to form a ridge 88. An SiO₂ dielectric film 93 is deposited on the p side, ap-electrode 89 made from Ni/Pt/Au is then formed on the p contact layer side, and an n-electrode 90 made from Ti/Al is formed on the n substrate side. Devices are then separated at a separation groove so as to give semiconductor laser devices.

In this way, a wafer in which polycrystalline AlGaN is deposited on an SiO₂ masking material when growing and selective growth is then carried out has a very low dislocation density on the mask. Dislocations in the <11-20> direction therefore also decrease, and dislocations present in the laser structure layer above the mask can be reduced.

As hereinbefore explained by reference to the examples, when a nitride semiconductor is grown on top of a wafer with a patterned masking material (SiO₂, etc.), forming polycrystals on top of the mask greatly decreases the dislocation density on the mask. Therefore, since the dislocations are bent in the <11-20> direction by the stress of the mask, etc., the dislocations are reduced and, furthermore, the dislocations that are bent from the <11-20> direction within the layer plane also decrease, thereby decreasing the dislocations present in the laser structure layer above the mask. Among the examples, some use growth equipment as a method for forming polycrystals on top of a mask, which is effective in reducing the number of steps.

Although one embodiment of the present invention is explained above with reference to the drawings, this is an exemplification of the present invention, and various other constitutions may be employed.

For example, in the above-mentioned examples, SiO₂ was used as a masking material, but another masking material such as SiNₓ or alumina may be used. The shape of the mask was a stripe pattern in the <11-20> direction, but it may be rectangular, circular, hexagonal, etc.

Furthermore, in order to reduce the dislocations, polycrystalline AlGaN was formed on top of the mask, but the present invention should not be construed as being limited thereto, and polycrystalline AlₓIn_{y}Ga_{1-x-y}N (0≦x≦1, 0≦y≦1) may be used.

Moreover, in the above-mentioned examples, a semiconductor laser was explained as an example, but the present invention may be applied to other light-emitting devices such as a light-emitting diode and, furthermore, to devices such as a photoreceptor and an electronic device.

The intermediate layer employed InGaN in the above-mentioned examples, but the present invention should not be construed as being limited thereto, and AlₓIn_{y}Ga_{1-x-y}N (0≦x≦1, 0≦y≦1) may be used.

What is claimed is:

1. A nitride semiconductor substrate comprising:
a group III nitride semiconductor substrate;
a mask formed over the group III nitride semiconductor substrate; and
a semiconductor multilayer film formed above the mask;
the mask having a polycrystalline material deposited on the surface thereof.

2. The nitride semiconductor substrate according to claim 1, wherein the polycrystalline material is formed from a material containing aluminum and nitrogen as essential elements.

3. The nitride semiconductor substrate according to claim 1, wherein voids are formed on the surface of the mask having the polycrystalline material.

4. The nitride semiconductor substrate according to claim 1, wherein the mask is provided on the surface of the group III nitride semiconductor substrate.

5. The nitride semiconductor substrate according to claim 1, wherein the group III nitride semiconductor substrate has a dislocation density in the vicinity of the surface thereof of 1×10⁷/cm² or less.

6. A nitride semiconductor device comprising:
a group III nitride semiconductor substrate;
a mask formed over the group III nitride semiconductor substrate; and
a semiconductor multilayer film formed above the mask, the semiconductor multilayer film including an active layer;
wherein the mask has a polycrystalline material deposited on the surface thereof.

7. The nitride semiconductor device according to claim 6, wherein the polycrystalline material is formed from a material containing aluminum and nitrogen as essential elements.

8. The nitride semiconductor device according to claim 6, wherein voids are formed on the surface of the mask having the polycrystalline material.

9. The nitride semiconductor device according to claim 6, wherein the mask is provided on the surface of the group III nitride semiconductor substrate.

10. The nitride semiconductor device according to claim 6, wherein the group III nitride semiconductor substrate has a dislocation density in the vicinity of the surface thereof of 1×10⁷/cm² or less.

11. The nitride semiconductor device according to claim 6, wherein the mask is provided in the vicinity of a device separating plane of the nitride semiconductor device.

12. A process for producing a nitride semiconductor substrate, the process comprising:
a step of forming a mask above a group III nitride semiconductor substrate;
a step of depositing a polycrystalline material on the surface of the mask; and
a step of forming a semiconductor multilayer film above the mask, the semiconductor multilayer film including an active layer.

13. The process for producing a nitride semiconductor substrate according to claim 12, wherein the step of depositing the polycrystalline material on the surface of the mask includes a step of depositing the polycrystalline material after bringing the surface of the mask into contact with an acid.

14. The process for producing a nitride semiconductor substrate according to claim 12, wherein in the step of depositing the polycrystalline material on the surface of the mask voids are formed on the surface of the mask.

15. The process for producing a nitride semiconductor substrate according to claim 12, wherein the mask is provided on the surface of the group III nitride semiconductor substrate.

16. The process for producing a nitride semiconductor substrate according to claim 12, wherein the group III nitride semiconductor substrate has a dislocation density in the vicinity of the surface thereof of 1×10⁷/cm² or less.

17. A process for producing a nitride semiconductor device, the process comprising:
a step of forming a mask above a group III nitride semiconductor substrate;
a step of depositing a polycrystalline material on the surface of the mask; and
a step of forming a semiconductor multilayer film above the mask, the semiconductor multilayer film including an active layer.

18. The process for producing a nitride semiconductor device according to claim 17, wherein the step of depositing the polycrystalline material on the surface of the mask includes a step of depositing the polycrystalline material after bringing the surface of the mask into contact with an acid.

19. The process for producing a nitride semiconductor device according to claim 17, wherein in the step of depositing the polycrystalline material on the surface of the mask voids are formed on the surface of the mask.

20. The process for producing a nitride semiconductor device according to claim 17, wherein the mask is provided on the surface of the group III nitride semiconductor substrate.

21. The process for producing a nitride semiconductor substrate according to claim 17, wherein the group III nitride semiconductor substrate has a dislocation density in the vicinity of the surface thereof of 1×10⁷/cm² or less.
